(19) United States
(12) Patent Application Publication
(10) Pub. No.: US 2018/0358453 A1
(43) Pub. Date: Dec. 13, 2018

(54) TUNNELING FIELD EFFECT TRANSISTOR

(71) Applicant: UNITED MICROELECTRONICS CORP., Hsin-Chu City (TW)

(72) Inventors: Hung-Wen Huang, New Taipei City (TW); Kai-Lin Lee, Kinmen County (TW); Ren-Yu He, Taichung City (TW); Chi-Hsiao Chen, Chiayi City (TW); Ting-Hsuan Kang, Taichung City (TW); Hao-Hsiang Yang, Taoyuan City (TW); An-Shih Shih, Taoyuan City (TW); Chuang-Han Hsieh, Tainan City (TW)

(21) Appl. No.: 15/642,360

(22) Filed: Jul. 6, 2017

(30) Foreign Application Priority Data
Jun. 13, 2017 (CN) 201710442176.6

(51) Int. Cl. H01L 29/66; H01L 29/49; H01L 29/786; H01L 21/28

(52) U.S. Cl. CPC H01L 29/66977; H01L 29/4908; H01L 29/66742; H01L 21/28088; H01L 29/78696

(57) ABSTRACT

The present invention provides a method of making a tunneling effect transistor (TFET), the method includes: a substrate is provided, having a fin structure disposed thereon, the fin structure includes a first conductive type, a dielectric layer is then formed on the substrate and on the fin structure, a gate trench is formed in the dielectric layer, and a first work function metal layer is formed in the gate trench, the first work function metal layer defines at least a left portion, a right portion and a central portion, an etching process is performed to remove the central portion of the first work function metal layer, and to form a recess between the left portion and the right portion of the first work function metal layer, afterwards, a second work function metal layer is formed and filled in the recess.

### BACKGROUND OF THE INVENTION

### 1. Field of the Invention

The present invention relates to the field of semiconductor processes, and more particularly to a tunneling field effect transistor structure and a method for forming the same.

### 2. Description of the Prior Art

The semiconductor integrated circuit industry has experienced rapid growth in the past several decades. Technological advances in semiconductor materials and design have produced increasingly smaller and more complex circuits. These material and design advances have been made possible as the technologies related to processing and manufacturing have also undergone technical advances. In the course of semiconductor evolution, the number of interconnected devices per unit of area has increased as the size of the smallest component that can be reliably created has decreased.

However, as the size of the smallest component has decreased, numerous challenges have risen. As features become closer, current leakage can become more noticeable, signals can crossover more easily, and power usage has become a significant concern. The semiconductor integrated circuit industry has produced numerous developments in its effort to continue the process of scaling. One of the developments is the potential replacement or supplementation of the conventional MOS field-effect transistor by the tunneling field-effect transistor (TFET).

Tunneling FETs are promising devices that may enable further scaling of power supply voltage without substantially increasing off-state leakage currents due to its sub-60 mV/dec subthreshold swing. However, existing TFETs have not been satisfactory in every respect.

### SUMMARY OF THE INVENTION

The present invention provides a tunnel field-effect transistor (TFET) structure, the TFET structure includes a substrate comprising a fin structure disposed thereon, the fin structure has a first conductivity type, a dielectric layer disposed on the substrate and the fin structure, the dielectric layer having a gate trench, a gate structure disposed in the gate trench, the gate structure comprising a gate conductive layer and a work function metal layer, the work function metal layer comprises a left portion, a right portion, and a central portion disposed between the right portion and the right portion, the material of the central portion is different from that of the left portion and the right portion, and a source and a drain, disposed on both sides of the fin structure on the substrate respectively.

The present invention provides a method of making a tunneling effect transistor (TFET), the method includes: a substrate is provided having a fin structure disposed thereon, the fin structure includes a first conductive type, a dielectric layer is then formed on the substrate and on the fin structure, a gate trench is formed in the dielectric layer, and a first work function metal layer is formed in the gate trench, the first work function metal layer defines at least a left portion, a right portion and a central portion, an etching process is performed to remove the central portion of the first work function metal layer, and to form a recess between the left portion and the right portion of the first work function metal layer, afterwards, a second work function metal layer is formed and filled in the recess.

In summary, one feature of the present invention is that using the TFET structure combining with the conventional fin transistor process, and the gate of the TFET structure is made of different work function materials, which can greatly reduce the sub-threshold swing slope (SS) of the TFET structure, it also apply to existing process environments.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 are schematic diagrams showing a method for producing a tunnel-effect transistor according to a first preferred embodiment of the present invention.

FIG. 10 is a band diagram showing the TFET structure of the present invention.

FIG. 11 is a characteristics diagram of the TFET structure.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

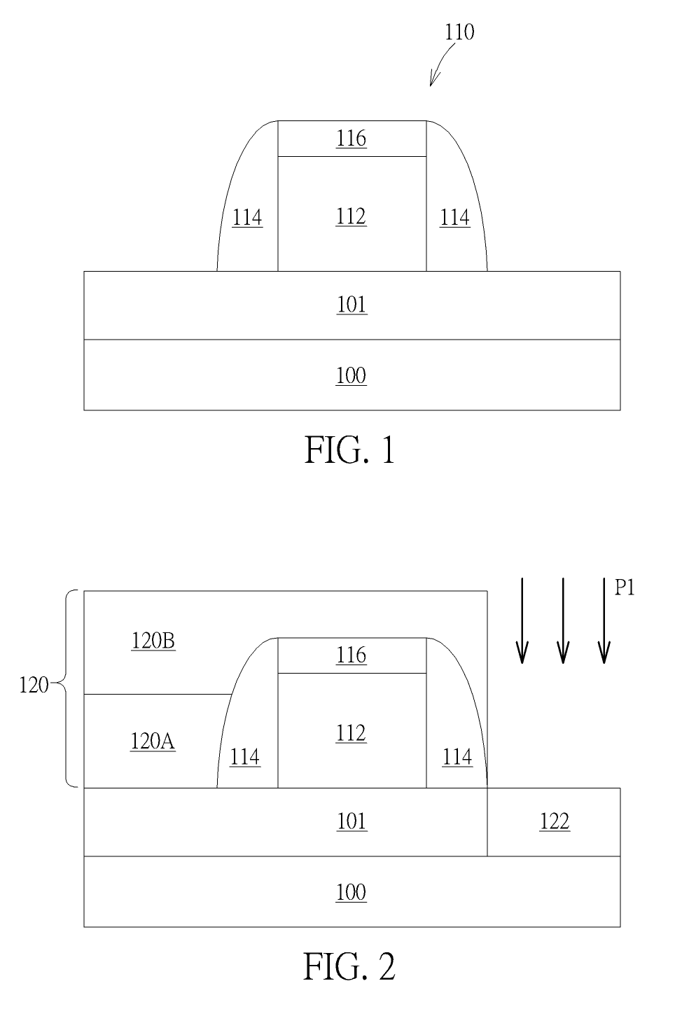

Please refer to FIGS. 1-9 that are schematic diagrams showing a method for producing a tunnel-effect transistor according to a first preferred embodiment of the present invention. As shown in FIG. 1, the present preferred embodiment provides a substrate 100, such as a silicon substrate, a silicon-containing substrate, or a silicon-on-insulator (SOI) substrate. The substrate 100 is formed with at least one fin structure 101, and the fin structure 101 preferably includes silicon material. In this embodiment, a silicon-on-insulating (SOI) substrate is included, and therefore, a silicon fin structure 101 is disposed on an insulating substrate 100.

It is noteworthy that, prior to the subsequent steps to form the tunneling field effect transistor (TFET), the specific ions may be doped into the fin structure 101 according to the type of the subsequent tunneling effect transistor (N type or P type). In the embodiment, the fin structure 101 may be doped to have an n-type resistivity before fabricating an n-type TFET; or the fin structure 101 may be doped to have a p-type resistivity before fabricating a p-type TFET. In the embodiment, when fabricating the n-type TFET, phosphorus atoms or arsenic atoms may be doped into the single-crystal silicon substrate to have a doping concentration within a range of 10¹³-10¹⁸ cm⁻³; when fabricating the p-type TFET, boron atoms may be doped into the single-crystal silicon substrate to have a doping concentration within 10¹³-10¹⁸ cm⁻³. In fact, the TFET does not have a specific restriction on doping type of the substrate as the conventional MOSFET does, since the MOSFET relies on an inversion of channel charge due to the field effect while a principle of the TFET is based on band-to-band tunneling of MOS-gated inverse biased p-i-n junction. For the p-i-n junction, the “i” layer may be a lightly doping layer or an intrinsic layer.

Afterwards, please still refer to FIG. 1, a dummy gate structure 110 is formed on the fin structure 101. The dummy gate structure 110 includes a sacrificial gate layer 112, two spacers 114 disposed on two sidewalls of the sacrificial gate layer 112 respectively, and optionally containing a mask layer 116 located at the top of the sacrificial gate layer 112. The material of the sacrificial gate layer 112 such as being polysilicon; the spacer 114 includes the materials such as silicon oxide or silicon nitride, and the mask layer 116 includes the material such as silicon oxide, silicon nitride or silicon oxynitride, but not limited thereto, and it can be adjusted according to actual requirements. In addition, in some embodiments, the mask layer 116 may also be omitted without being formed.

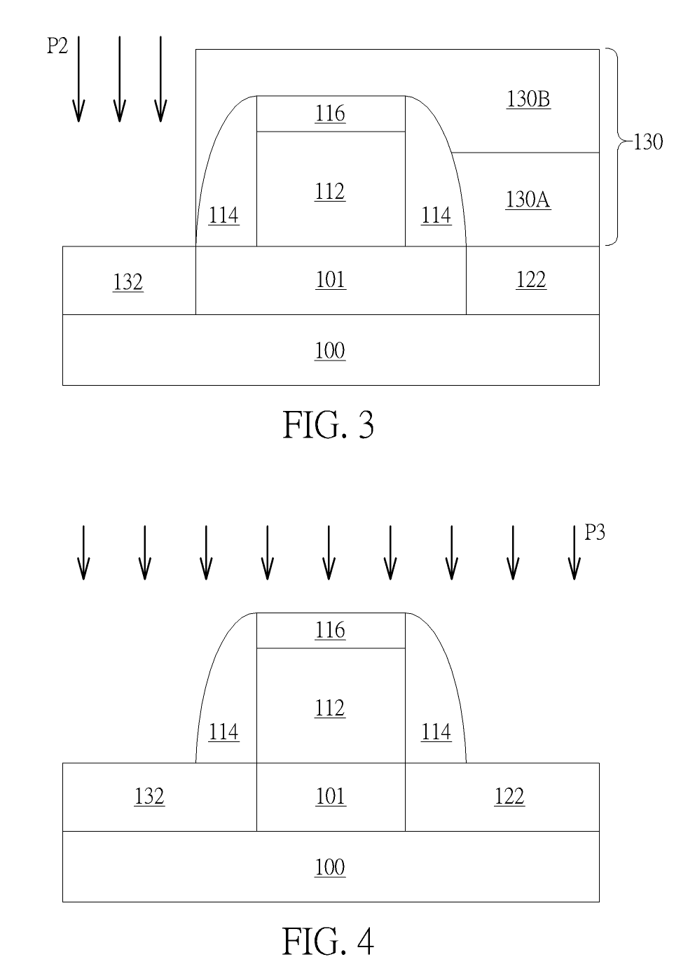

Next, please refer to FIG. 2, a mask layer 120 is formed, covering parts of the fin structure 101 and parts of the dummy gate structure 110, and also exposing the portion of the fin structure 101. Afterwards, anion dopant step P1 is performed, to form a source region 122 in the fin structure 101 on one side of the dummy gate structure 110. Then, as shown in FIG. 3, after removing the mask layer 120, another mask layer 130 is formed again, covering the source region 122 and the dummy gate structure 110, and performing another ion doping step P2, a drain region 132 is therefore formed in the fin structure 101 on another side of the gate structure 110 (opposite to the side of the source region 122).

In the steps mentioned above, the mask layer 120 or the mask layer 130 may be a single layer or a multi-layer structure. In the present embodiment, the mask layer 120 includes a bottom anti-reflection layer 120A and a photoresist layer 120B. The mask layer 130 includes a bottom anti-reflective layer 130A and a photoresist layer 130B. In addition, in this embodiment, taking an N-type TFET as an example, the source region 122 is doped with boron ions, therefore the source region 122 has a P-conductivity type, and the substrate (for example, the fin structure 101) and the drain region 132 are doped with phosphorus ions or arsenic ions, and they have an N conductivity type. When the N-type TFET is actuated, the source region 122 is grounded and a positive voltage is applied to the gate (subsequently formed). On the other hand, in the case of a P-type TFET, the source region 122 contains an N conductivity type, and the substrate (e.g., the fin structure 101) and the drain region 132 includes P conductivity type. When the P-type TFET is actuated, the source region 122 is grounded and a negative voltage is applied to the gate.

In addition, when the above-mentioned ion doping is completed, the doped ions are activated. Specifically, referring to FIG. 4, after removing the mask layer 130, a heat treatment step P3, specifically known activation annealing technologies may be used, such as rapid thermal processing, spike annealing and laser annealing, so that the doped impurity atoms may be activated and a heavily doped source region 122 and a drain region 132 are formed. It is to be noted that the range of the source region 122 and the drain region 132 is slightly enlarged during the heat treatment step P3. Preferably, the range of the source region 122 and the drain region 132 will extend below the sacrificial gate layer 112, so that the following-formed gate structure will be closer to the source region 122 and the drain region 132, thereby enhancing the performance of TFET.

In addition, the formation sequence of the source region 122 and the drain region 132 may be reversed. In other words, the source region 122 may be formed after the drain region 132 is formed, which is also within the scope of the present invention.

Next, as shown in FIG. 5, a contact etch stop layer (CESL) 140 and a dielectric layer 142 are sequentially formed on the substrate 100, and a planarization step is performed to remove the extra CESL 140 and the dielectric layer 142, to expose the surface of the mask layer 116 (or in other embodiments, exposing the sacrificial gate layer 112 if the mask layer 116 is not formed).

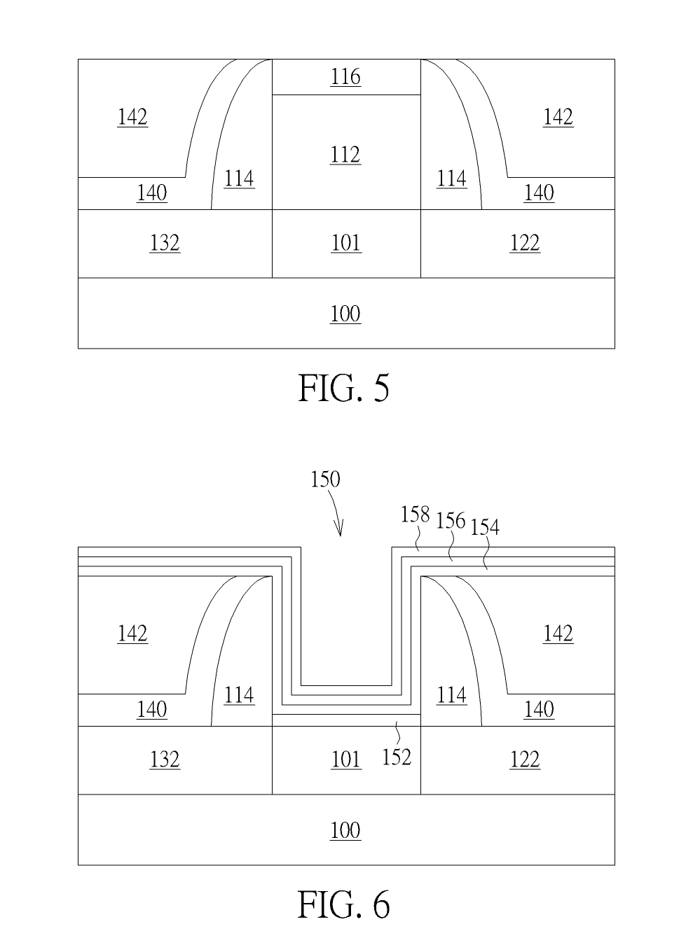

As shown in FIG. 6, the sacrificial gate layer 112 and the mask layer 116 are removed to form a gate trench 150. An interfacial layer 152, a high-k dielectric layer 154, a bottom barrier layer 156 and a first work function metal layer 158 are formed in the gate trench 150 in sequence.

In the steps mentioned above, the high-k dielectric layer 154 can include high-k material such as rare earth metal oxide. The high-k dielectric layer 104 can include material selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂) , strontium titanate oxide (SrTiO₃) , zirconium silicon oxide (ZrSiO₄), hafnium zirconium oxide (HfZrO₄), strontium bismuth tantalate, (SrBi₂Ta₂O₉, SBT), lead zirconate titanate (PbZrxTi₁-xO₃, PZT), and barium strontium titanate (BaxSr₁-xTiO₃, BST). In the preferred embodiment, the bottom barrier layer 156 can include titanium nitride (TiN). The first work function metal layer 158 includes an N-type work function metal layer such as titanium aluminide (TiAl), zirconium aluminide (ZrAl), tungsten aluminide (WAl), tantalum aluminide (TaAl), or hafnium aluminide (HfAl), but not limited to this. The first work function metal layer 158 may also be a P-type work function metal layer having a P conductivity type. In the present embodiment, the first work function metal layer 158 is a TiAl layer having a work function of about 4.1 electron volts (eV).

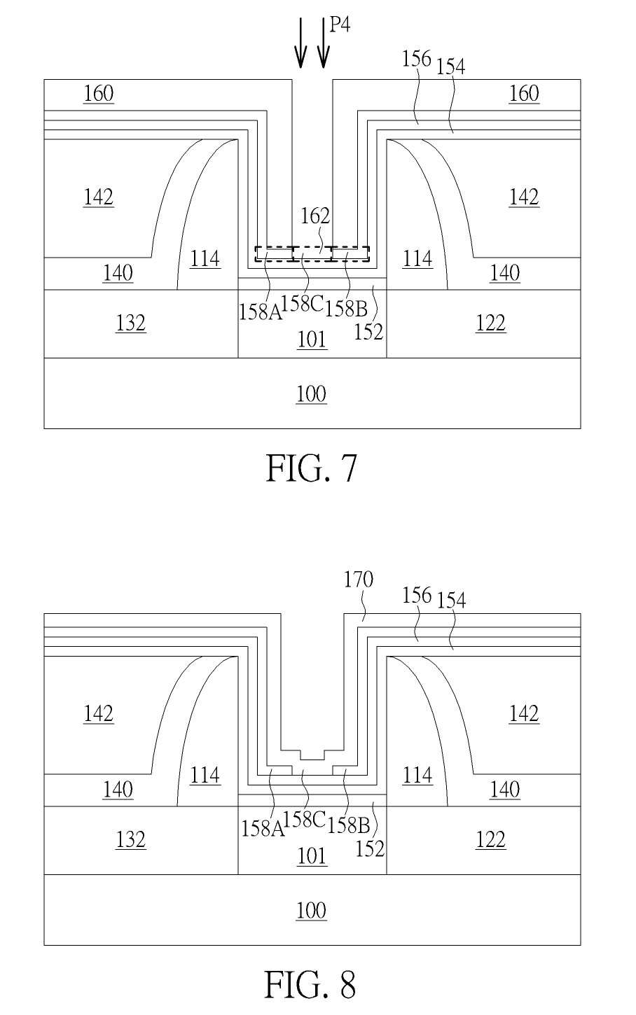

Next, as shown in FIG. 7, a photoresist layer 160 is formed in the gate trench 150, and the photoresist layer 160 exposes a portion of the first work function metal layer 158. An etching step P4 is then performed to remove parts of the first work function metal layer 158 and to form a recess 162. In particular, the first work function metal layer 158 at the bottom of the gate trench 150 may be defined as a left portion 158A, a right portion 158B, and a central portion 158C. The etching step P4 removes the central portion 158C. After the central portion 158C is removed, the recess 162 is formed between the left portion 158A and the right portion 158B. Thereafter, as shown in FIG. 8, the photoresist layer 160 is removed, and a second work function metal layer 170 is then formed, to fill at least in the recess 162. In other words, the central portion 158C is filled with the second work function metal layer 170. The second work function metal layer 170 may be a P-type work function metal layer having a p conductivity type, such as titanium nitride (TiN), titanium carbide (TiC), tantalum nitride, TaN), tantalum carbide (TaC), tungsten carbide (WC), or aluminum titanium nitride (TiAlN), but are not limited thereto. In the present invention, the second work function metal layer 170 is a TiN layer having a work function of about 4.5 electron volts (eV). In addition, the second work function metal layer 170 is different from the first work function metal layer 158, or at least, they have different work functions.

In addition, in other embodiments of the present invention, it is also possible to omit the photoresist layer 160, and directly remove the portion of the work function metal layer 158 and to form the recess 162 through a vertical etching process, or to adjust the work function of parts of area of the work function metal layer 158 by ion doping. It should also be within the scope of the present invention.

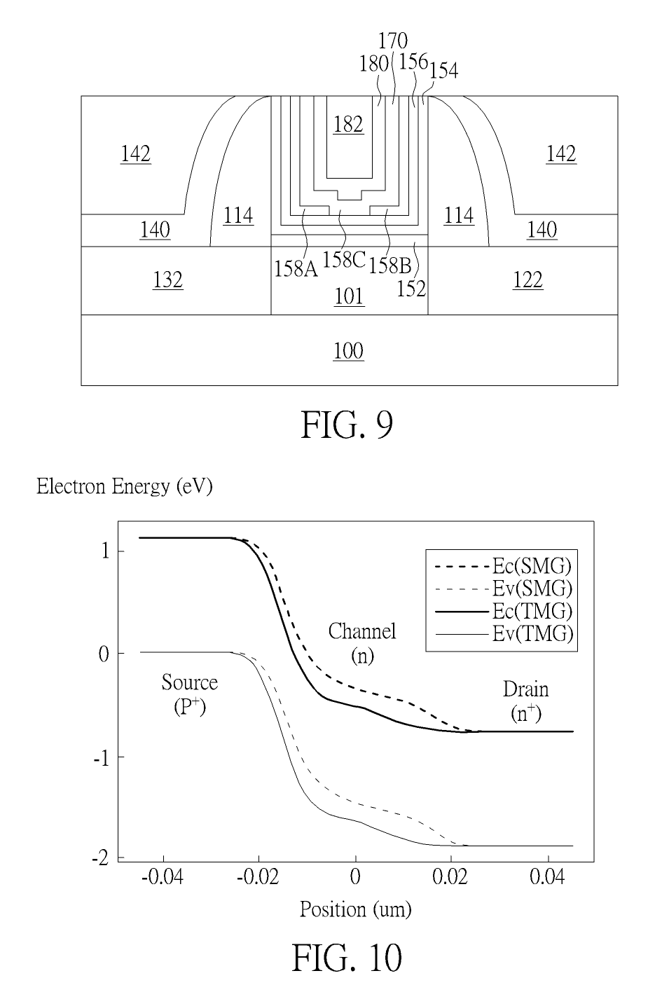

Thereafter, as shown in FIG. 9, a filling metal layer 182 is formed in the first gate trench 150. Additionally, a top barrier layer 180 is preferably formed between the second work function metal layer 170 and the filling metal layer 182. The top barrier layer 180 can include TiN, but not limited to this. The filling metal layer 182 is formed to fill up the first gate trench 150. The filling metal layer 182 includes materials with low resistance and superior gap-filling characteristic, such as Al, TiAl, or titanium aluminum oxide (TiAlO), but not limited to this. Afterwards, a planarization process (not shown) is performed to remove the extra material layers disposed on the dielectric layer 142 (such as the second work function metal layer 170 or the filler metal layer 182). At this step, the tunneling field effect transistor (TFET) structure 190 of the present invention has been completed.

As shown in FIG. 9, the gate of the TFET structure 190 contains different kinds of work function metal layers. Specifically, the right portion 158B and the left portion 158A near the source region 122 and the drain region 132 contain the first work function metal layer 158 respectively, and the central portion 158C near the channel region that is disposed between the source region 122 and the drain region 132 includes the second work function metal layer 170.

According to an embodiment of the present invention, the gate of the TFET structure 190 contains different work function materials that can control and influence the potential diagram of the TFET structure 190. Taking an N-type TFET structure 190 as an example, the work function metal layer near the source of the source and drain terminals has a lower work function, and the work function metal layer near the channel portion has a higher work function. Therefore, the TFET with a gate made of different materials can be formed.

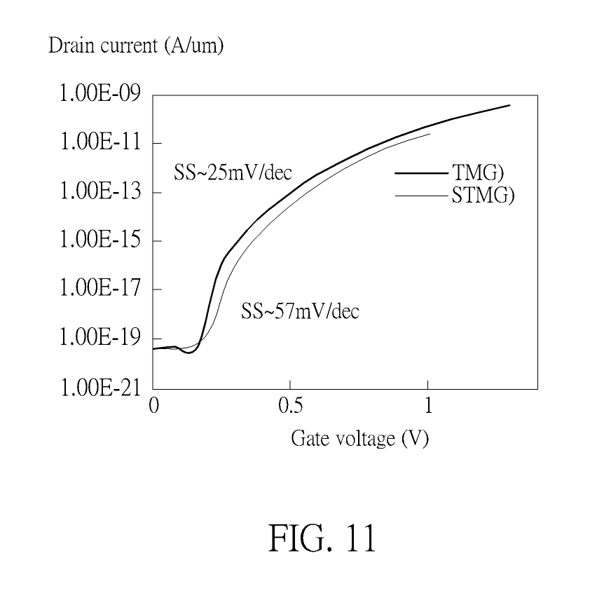

FIG. 10 is a band diagram showing the TFET structure of the present invention. FIG. 11 is a characteristics diagram of the TFET structure. FIGS. 10-11 depicts comparison of the TFET structure of the present invention (with gate made of different work function materials, known as hetero material gate, HMG) and TFET with single material gate (SMG) with single layer work function layer. As shown in FIG. 10, compared with SMG TFET, the energy band of the HMG TFET structure of the present invention is slightly decreased in the vicinity of the source region and the vicinity of the channel region, which means that the electrons are more likely to pass through the energy band. As shown in FIG. 11, the sub-threshold swing slope (SS) of the TFET structure shown in the present invention is significantly lower than that of the SMG TFET structure, which is only about 25 mV/dec.

In summary, one feature of the present invention is that using the TFET structure combining with the conventional fin transistor process, and the gate of the TFET structure is made of different work function materials, which can greatly reduce the sub-threshold swing slope (SS) of the TFET structure and also apply to existing process environments.

Those skilled in the art will readily observe that numerous modifications and alterations of the device and method may be made while retaining the teachings of the invention. Accordingly, the above disclosure should be construed as limited only by the metes and bounds of the appended claims.

1. A tunnel field-effect transistor (TFET) structure comprising:
a substrate comprising a fin structure disposed thereon, wherein the fin structure has a first conductivity type;
a dielectric layer disposed on the substrate and the fin structure, the dielectric layer having a gate trench;
a gate structure disposed in the gate trench, the gate structure comprising a gate conductive layer, a bottom barrier layer, a first work function metal layer and a second work function metal layer, wherein the second work function metal layer disposed on the first work function metal layer, and wherein both the first work function metal layer and the second work function metal layer contact the bottom barrier layer directly; and
a source and a drain, disposed on both sides of the fin structure on the substrate respectively.

2. The tunnel field-effect transistor structure of claim 1, wherein the first work function metal layer and the second work function metal layer comprises different materials.

3. The tunnel field-effect transistor structure of claim 1, wherein the first work function metal layer only covers parts of the bottom barrier layer.

4. The tunnel field-effect transistor structure of claim 3, wherein parts of the second work function metal layer is disposed between the first work function metal.

5. (canceled)

6. The tunnel field-effect transistor structure of claim 1, wherein the drain comprises a first conductivity type.

7. The tunnel field-effect transistor structure of claim 6, wherein the source comprises a second conductivity type, the second conductivity type is complementary to the first conductivity type.

8. The tunnel field-effect transistor structure of claim 1, wherein a top surface of the fin structure, a top surface of the source and a top surface of the drain are disposed on a same level.

9. The tunnel field-effect transistor structure of claim 1, further comprising a high dielectric constant layer disposed in the gate trench.

10. A method of forming a tunneling field-effect transistor (TFET), comprising:
providing a substrate, having a fin structure disposed thereon, wherein the fin structure has a first conductivity type;
forming a dielectric layer on the substrate and on the fin structure;
forming a gate trench in the dielectric layer;
forming a first work function metal layer in the gate trench, wherein the first work function metal layer comprises at least a left portion, a right portion and a central portion;
performing an etching process to remove the central portion of the first work function metal layer, and to form a recess between the left portion and the right portion of the first work function metal layer; and
forming a second work function metal layer and filling in the recess.

11. The method of claim 10, wherein the first work function metal layer and the second work function metal layer comprise different materials.

12. The method of claim 11, wherein the first work function metal layer comprises titanium aluminum oxide.

13. The method of claim 11, wherein the second work function metal layer comprises titanium nitride or tantalum nitride.

14. The method of claim 10, further comprising forming a source and a drain on both sides of the fin structure on the substrate respectively.

15. The method of claim 14, wherein the fin structure and the drain comprise a first conductivity type.

16. The method of claim 15, wherein the source comprises a second conductivity type, the second conductivity type is complementary to the first conductivity type.

17. The method of claim 10, further comprising forming a gate conductive layer on the second work function metal layer.

18. The method of claim 10, wherein the left portion, the right portion and the central portion of top surface of the first work function metal layer are disposed on a same level.

19. The method of claim 10, wherein a top surface of the fin structure, a top surface of the source and a top surface of the drain are disposed on a same level.

20. The method of claim 10, further comprising forming a high-k dielectric layer and a bottom barrier layer in the gate trench.
